(19) United States
(12) Patent Application Publication
(10) Pub. No.: US 2022/0242672 A1
(43) Pub. Date: Aug. 4, 2022

(54) Optimized System and Method for Transporting and Moving Substrates in a Modular Coating Facility

(71) Applicant: Oerlikon Surface Solutions AG, Pfäffikon, Pfäffikon (CH)

(72) Inventors: Markus Esselbach, Feldkirch (AT); Simon Abraham, Sargans (CH); Michael Ebenberger, Sargans (CH); Andreas Flueck, Bad Ragaz (CH); Othmar Zueger, Triesen (LI)

(21) Appl. No.: 17/432,261

(22) PCT Filed: Feb. 20, 2020
(86) PCT No.: PCT/EP2020/000049

§ 371 Date: Aug. 19, 2021

Related U.S. Application Data
(60) Provisional application No. 62/807,965, filed on Feb. 20, 2019.

(51) Int. Cl. B65G 23/06; B05B 13/02

(52) U.S. Cl. CPC B65G 23/06; B65G 2812/02287; B05B 13/0221

(57) ABSTRACT

The present invention provides a solution for coating substrates which are moved on a carrier that can move from painting, coating or treatment modules in a continuous inline production facility having a system which allows to easily switch between a back and forth limited rotational movement, called rocking mode, for critical processes such as physical vapor deposition (PVD) coating, UV hardening and IR flashing, and a continuous rotational movement of the substrates when the substrates are in a painting or drying process module.

The present invention provides a solution for coating substrates which are moved on a carrier that can move from painting, coating or treatment modules in a continuous inline production facility having a system which allows to easily switch between a back and forth limited rotational movement, called rocking mode, for critical processes such as physical vapor deposition (PVD) coating, UV hardening and IR flashing, and a continuous rotational movement of the substrates when the substrates are in a painting or drying process module.

### TECHNICAL BACKGROUND

Processes to paint, coat and treat substrates in complex processing lines are well described by Ribero et al. (U.S. Pat. No. 10,016,774 B2), Spangler et al. (US 2009/0277384 A1) and Keckes et al. (U.S. Pat. No. 9,476,116 B2, U.S. Pat. No. 9,529,450 B2). The economic advantage of using a modular inline approach to allow a serial processing instead of using large different treatment chambers in batch processes is evident.

However, the major challenge is that each module make use of different processes, such as cleaning of the substrate by etching, ultrasound or plasma process; the coating of single or multilayer systems by physical vapor deposition (PVD) either by magnetron sputtering or arc discharge, using at least one sputter target per PVD module; the painting process to spray a coating dispersion, UV-hardening lacquer; the treatment of the lacquer by backing the substrate through an heat source, such as IR source, curing and/or hardening the lacquer by UV emission sources. All these processes require specific positions and movements of the substrates. The rate of each process is quite fast within a few minutes or faster. It is therefore critical to be able to switch from one type of movement of the substrate to another without interrupting the continuous process.

The transport and movement of the substrates between each modules is usually done by means of a carrier which is moved through a transport belt. The carrier is supporting one or several rotating spindles, usually of cylindrical form on which small sized substrates are mounted. The cylinder is rotating through the spindle at different rotation speed and can be synchronized with the movement of the transport belt within a processing module.

### Underlaying Problem

One of the challenge is to provide a simple and economic solution to transport the substrates between each of the modules and at the same time provide optimized movements of the substrates adapted to the different processes in the modules without increasing the complexity of the system.

For example, in PVD processes, it is very important to accurately position the substrates with respect to the target, where the material is evaporated. If parts are not moved during the deposition process, the produced layer will most likely not be homogenous, due to the inhomogeneity of the evaporation and diffusion of the material from the surface of the target. This is why the substrates are moved in front of the target through a rotating cylinder. The exposure time in front of the target determines the coating thickness and coating thickness distribution.

On the other hand, spraying of UV-hardening lacquer, for example, will require a different movement of the substrate as the painting of suspension particles onto the substrate will still remain in a fluid phase before the hardening process occurs and could run out if the part is not moved in a certain way. Heat treatment by IR or UV curing of the lacquer will require a more homogenous movement of the substrate in order to spread the heat or the light in a more homogenous way onto the substrate.

The simplest solution in this case is to use the same rotational movement for each process allowing some adjustment on the rotation speed for each process. This would be acceptable in most of the cases when the substrates to be coated or painted are rather small and can be placed on the cylindrical support.

This specific state of the art case is illustrated in FIG. 1 where two spindles supporting two cylinders are (5) are placed in front of the sputter targets (4) inside a physical vapor deposition chamber (1). The transport belt (3) allows to perform an additional back and forth movement in order to improve the coating quality and coating distribution on the substrates. The mechanical solution for this simple rotational mode is shown in FIG. 2 where the spindles (5) are mounted on the carrier (2). The spindles have a spindle gear (51) which is driven by a moving chain (41) and controlled by a servo motor (40)

However, this type of movement is quite limiting when considering larger substrates, where a simple rotation would not be sufficient to produce the desired coating quality. This situation is illustrated in FIG. 3 where two larger substrates are mounted on the spindles in place of the cylindrical substrate supports. It is clear from the short distance between the sputter target (4) and the substrate (7) to get an acceptable coating, that the spindles cannot rotate completely anymore like in the free cylindrical rotational mode. The only possibility is to move the substrates using the transport belt in a back and forth horizontal movement in order to optimize the coating thickness distribution on the substrates. These movements are however limited by the dimensions of the module. Since typical large substrate dimensions are between 0.6 m and 1.5 m, the back and forth movement would be limited to about −300 mm to 300 mm. Even with this additional back and forth movement of the substrates in front of the targets, the coating would be thicker on the edge as the substrates are not moving completely away from the target and there would be an overlapping of the other target while the substrate is passing by.

### OBJECTIVE OF THE INVENTION

The objective of the invention is to provide a carrier that can move from one painting, coating or treatment module in a continuous inline production facility having a system that allows to easily switch between a back and forth limited rotational movement, called rocking mode and a rotational movement of the substrates. The inventive system, as well as the preferred and additional embodiments are described more in detail in the following paragraphs.

The inventive solution and the different possible enabled movements of the substrates are illustrated in FIGS. 4a and 4b. FIG. 4a showing the position for the rocking mode and FIG. 4b the free rotational mode. A carrier (2) that can move from one painting, coating or treatment module to another through a transport belt, comprises at least one spindle (7) supporting a substrate holder or a large but rather flat substrate which is between 0.6 m to 1.5 m long. Rather flat means that the aspect ratio between the length and the height of the substrate is higher or equal than 2 but not higher than 1500. A coupling gear (30) located close to the base of the carrier is driven by a chain (41), located preferably on the lower part of the carrier and controlled by a servo motor (40) which produces either continuous or discontinuous movements of the chain in both directions. A coupling rod (31) is attached on the coupling gear (30) at a certain radial distance of the axis and attached as well on a spindle clamp (32) which is aligned with the axis of the spindle. The spindle clamp (32) is preferably of a disc shape and has an opening on the top which has a certain shape, either conical, rectangular or at is least angular. The axis of the spindle has at least one part (72) which has a shape that is partially matching the shape of the open insert of the spindle clamp, preferably rectangular, so that when the spindle axis is positioned inside the opening of the spindle clamp, the spindle is mechanically linked and can rotate together with the spindle clamp.

The coupling rod length and the location of the attachment of the rod on the spindle clamp and coupling gear is set so that when the coupling gear is rotating completely, the spindle makes a back and forth movement of preferably +30° to −30° measured with respect to the horizontal plane of the carrier. The frequency of the back and forth movement or rocking movement of the spindle can be set by setting the speed of the chain through the servo motor. The movement of the rocking movement can be either continuous or discontinuous (indexed) at certain given angles and given time during the process.

The rocking movement of the spindle can be complemented by a horizontal back and forth movement of the carrier through the transport belt. Depending on the dimension of the module, this distance can be of about −300 mm to 300 mm in the PVD coating chamber.

The frequency of the rocking movement between the two maximum angles, preferably +30° and −30° can be varied between 0.1 and 10 Hz.

The inventive apparatus allows to switch from the rocking mode, where the coupling gear and the spindle clamps are coupled together to the classical rotational mode (FIG. 4b), by moving the spindle upwards so that the axis of the spindle moves outside of the spindle clamp opening. This is done by lifting the carrier by hydraulic motors on the bottom. The spindle comprises a spindle gear (71) which can be rotated through a chain system (61) located on the upper side of the carrier and driven by another servo motor (60). In this configuration the spindle is no more mechanically coupled with the spindle clamp and can rotate continuously with the continuous movement of the chain. The chain however is controlled by a servo motor which allows to also produce discontinuous movements in both directions. Once the continuous rotation mode is no more needed, the spindle can go back to the start horizontal position when the carrier is moved back in the lower initial position.

A second spindle or more can be positioned on the carrier. In case of two spindles, the coupling gear is located between the two spindles. The configuration of the coupling rod and spindle clamp being symmetrical on the second spindle.

This type of gear system allows to quickly switch between a continuous rotation mode and a rocking mode when the carrier is moving from one module to the other.

FIGS. 5a, 5b and 5c show the different positions the spindles (7) can have in a PVD coating chamber (1) when in the rocking mode. The initial position is shown in FIG. 5a where the substrates (7) are directly located in front of the sputter targets (4). The substrates can be moved on the far left position of the chamber at maximum distances of 300 mm from the initial position as seen in FIG. 5b. This horizontal movement is done by the transport belt. Here the angle of −30° allows to have a larger distance between the edge of the substrate and the target, allowing to compensate for coating thickness inhomogeneities at the edges of the substrate. FIG. 5c shows the symmetrical situation when the substrates are positioned on the far right side of the coating chamber. Here the angle of the substrate is at 30° from the horizontal.

The positions shown in the FIGS. 5a, 5b, 5c can be either set as static position or as smooth combined movements between the back and forth horizontal movement and the rocking movement of the substrate, which are defined by their respective frequencies of movement. This adds a parameter to better control the coating quality, exposure to heat or drying process in the different processing modules.

Another advantage of the inventive apparatus is the possibility to additionally combine mechanical movements of the substrates over the targets during PVD coating and change the power of the sputtering source on the target according to the specific position of the substrates in the coating chamber. In particular, the back and forth movement can be synchronized with the power source of the magnetron sputtering of the targets to allow a smooth transition between a low power and high power while the substrate is close or away from the target. This way a control of the coating thickness is possible while having a limited back and forth movement of the carrier inside the coating module.

FIGS. 6a, 6b and 6c show another embodiment of the invention, where the coupling gear (30) driven by the lower chain (41) is axially coupled with a main transmission gear (300) which is coupled with a smaller gear (301) allowing to fine tune the rocking angles which can vary with respect to the dimensions of the carrier. The coupling rod comprises also an adjustment device (302) having two screws (303) on each side which allow controlling and adjusting the length of the coupling rod. This adjustment is necessary due to the manufacture tolerance variations, especially when the distances between the spindles and coupling gear are rather large.

The specific positioning of the mechanical link and radius where the spindle clamp is attached is designed in such a way that the complete rotation of the small gear only allows the movement of spindle gear between −30° and 30° from the horizontal plane. These limitations of the angles are critical in some processes because the distances between the targets, IR lamps or UV sources and substrates in the process modules are very narrow and critical. It is also a way to have a mechanical limitation so that the expensive UV emission sources cannot be damaged during processing by mistakenly producing a complete rotation of the larger substrate in the UV processing module.

Another advantage of the inventive apparatus is to be able to combine the rocking movement of the larger substrates when located in one module, for example, during PVD coating or UV curing, and change the rocking mode into a fully rotational mode when the larger substrates are located in another module, for example, during the painting process. In this specific case a rocking movement or static positioning of the larger substrate would not be optimum as the painting of the paint or UV-hardening lacquer in form of suspensions would still remain in a fluid phase before the hardening process has started and could run off if the parts are not constantly moved. The heat treatment by heat source or IR source also require rotational movement of the substrates in order to spread the heat of the IR source in a more homogenous way over the complete area of the substrate.

With the different embodiments shown as illustration and not limiting to the invention, it is shown that the inventive apparatus allows the coating and treatment of larger substrates, keep a simple transport and movement system limited to at least two servo motors, two chains and a few gears that can be quickly adjusted between the different modules and at the same time keep the standard process of coating smaller samples using spindles.

### LIST OF FIGURES

FIG. 1 shows a general overview of the carrier device transporting two rotatable cylindrical spindles in a PVD coating chamber and positioned in front of two sputter targets.

FIG. 2 shows the mechanical setup of the rotational mode of the cylindrical spindles which are driven through the gear spindle by a chain which is moved by a servo motor.

FIG. 3 shows a general overview of the carrier device transporting two spindles for large and rather flat substrates in a PVD coating chamber and positioned in front of two sputter targets.

FIG. 4a shows the mechanical setup in the rocking mode of the two spindles carrying is larger and flat substrates positioned in the lower position where the central gear is producing the rocking movement of the spindles through the lower chain.

FIG. 4b shows the mechanical setup in the rotational mode of the two spindles carrying larger and rather flat substrates positioned in the upper position where the spindle gear is producing the rotational movement of the spindles through the upper chain.

FIG. 5a shows the possible angles (between −30 and 30° from the horizontal plane) in the rocking mode of the two spindles carrying the larger and rather flat substrates in front of the PVD targets in a PVD coating machine.

FIG. 5b shows the two spindles in the rocking mode which are positioned on the leftmost side position with respect to the PVD targets and at a minimum rocking angle of −30°.

FIG. 5c shows the two spindles in the rocking mode which are positioned on the rightmost side position with respect to the PVD targets and at a maximum rocking angle of +300.

FIG. 6a shows the detailed mechanism in a preferred embodiment of the rocking mode when the spindle is positioned inside the spindle clamp and at an angle of 0° with the horizontal

FIG. 6b shows the detailed mechanism in a preferred embodiment of the rocking mode when the spindle is positioned inside the spindle clamp and at an angle of 30° with the horizontal

FIG. 6c shows the detailed top view of the gear mechanism in a preferred embodiment of the rocking mode showing the transmission gears and coupling rod.

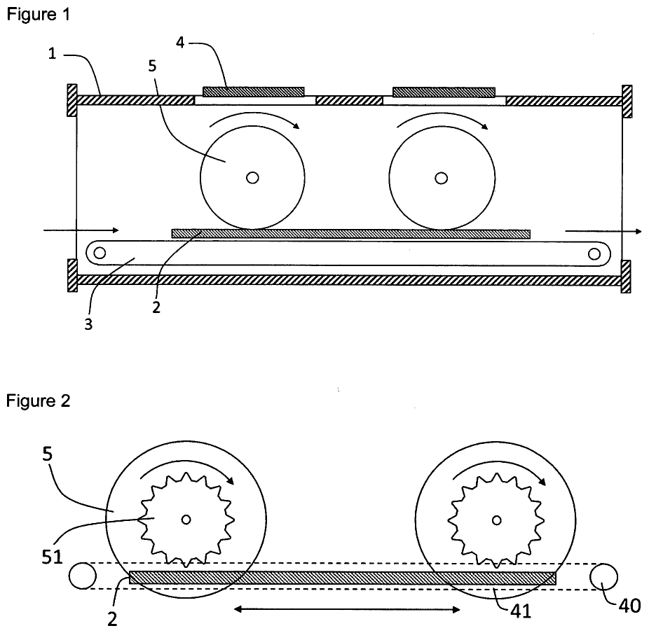

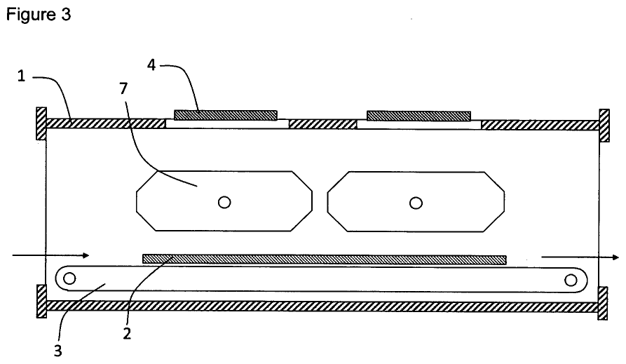

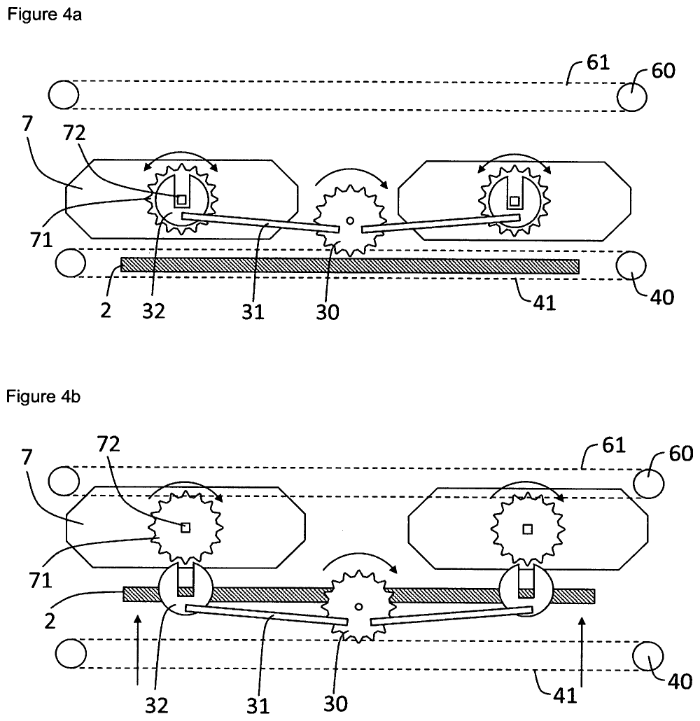

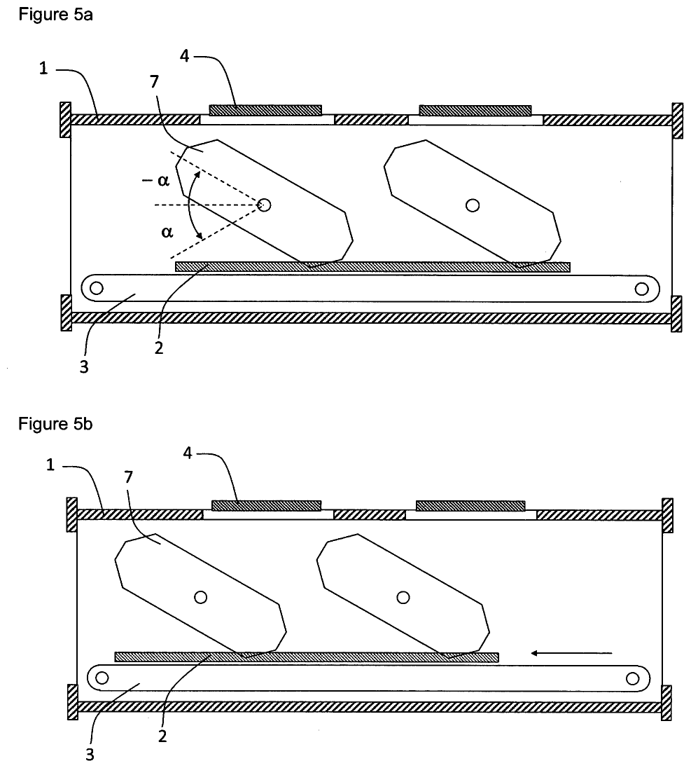

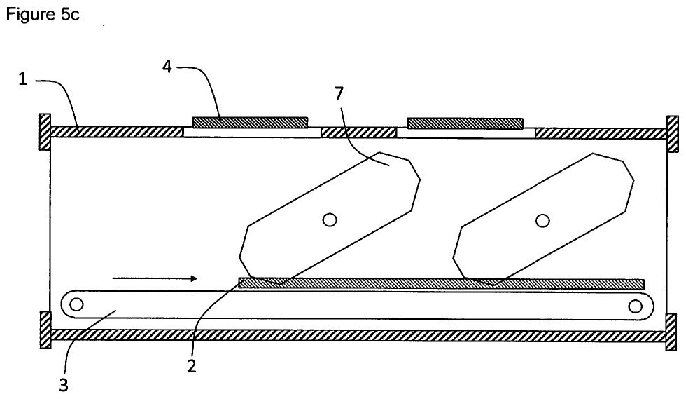

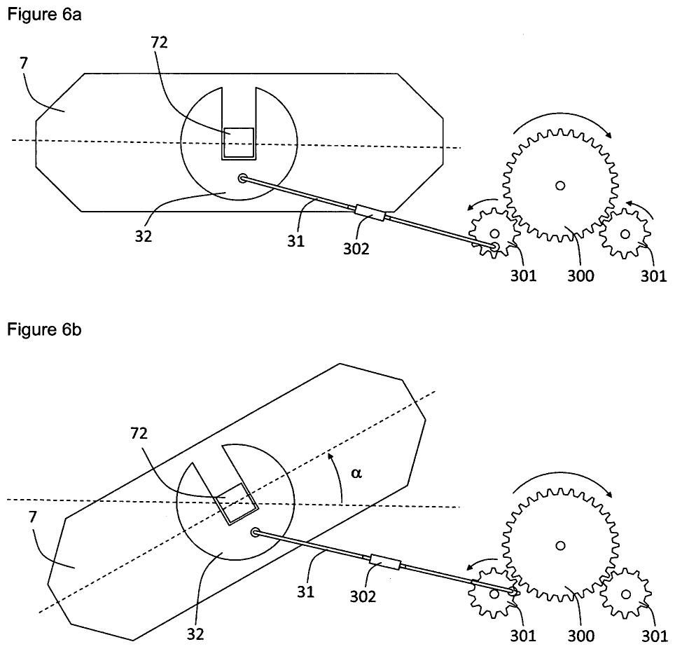

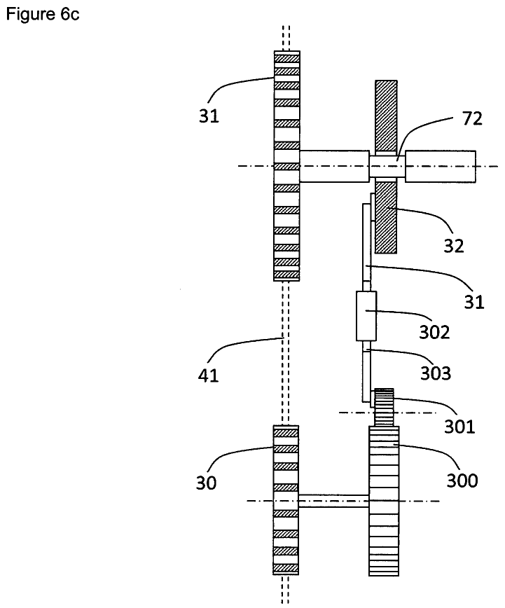

### LIST OF REFERENCE NUMBERS

1 physical vapor deposition (PVD) coating chamber
2 carrier
3 transport belt
4 sputter target
5 spindle
7 substrate holder
30 coupling gear
31 coupling rod
32 spindle clamp
40 lower servo motor
41 lower chain
60 upper servo motor
61 upper chain
71 spindle gear
72 special shaped spindle axis
300 transmission gear
301 smaller coupling gear
302 adjustable device for coupling rod
303 screw for adjustment of coupling rod length

1-10. (canceled)

11. A carrier that can move from one painting, coating or treatment module to another through a transport belt, the carrier comprising:
at least one spindle supporting a substrate holder;
the spindle comprising a spindle gear;
a coupling gear which is driven by a chain, wherein the coupling gear is coupled through a coupling rod to a spindle clamp, wherein the spindle clamp is positioned on the axis of the at least one spindle and having at least one opening allowing the axis of the spindle to be moved in and out of the spindle clamp
wherein
the axis of the spindle comprises at least one part which has a shape that is at least partially matching the shape of the open insert of the spindle clamp so that the axis of the spindle is mechanically coupled with the spindle clamp and allows the spindle axis to rotate together with the spindle clamp when the spindle axis is positioned inside the opening of the spindle clamp.

12. The carrier according to claim 11 wherein the radius of the attachment of the coupling rod with respect to the axis of the coupling gear, the length of the coupling rod and the radius of the attachment of the coupling rod with respect to the axis of the spindle clamp axis is set so that a continuous rotation of the coupling gear produces a back and forth movement of the spindle clamp on its axis.

13. The carrier according to claim 11 wherein the coupling gear is axially coupled to another transmission gear which is driving a smaller gear on which the coupling rod is attached to, so that a complete rotation of the smaller gear produces a back and forth movement of the spindle clamp.

14. The carrier according to claim 12 wherein the back and forth movement of the spindle clamp is between 30 and −30° with respect to the horizontal parallel to the carrier top surface.

15. The carrier according to claim 12 wherein the carrier can be moved horizontally inside a module through the transport belt during the painting, coating or treatment process and the back and forth rotational movement of the spindle.

16. The carrier according to claim 11 wherein at least one spindle can be moved by lifting the carrier so that the axis of the at least one spindle is moved outside the opening of the spindle clamp and is decoupled from it.

17. The carrier according to claim 16 wherein at least one spindle can be rotated by a moving chain through the spindle gear.

18. The carrier according to claim 17 wherein at least one spindle can rotate freely at least at any angle or in a continuous rotation in synchronization with the movement of the moving chain.

19. A method for moving at least one spindle on a carrier that can move from one painting, coating or treatment module to another through a transport belt, the carrier comprising:
at least one spindle supporting a substrate holder;
the spindle comprising a spindle gear;
a coupling gear which is driven by a chain, wherein the coupling gear is coupled through a coupling rod to a spindle clamp, wherein the spindle clamp is positioned on the axis of the at least one spindle and having at least one opening allowing the axis of the spindle to be moved in and out of the spindle clamp
wherein
the axis of the spindle comprises at least one part which has a shape that is at least partially matching the shape of the open insert of the spindle clamp so that the axis of the spindle is mechanically coupled with the spindle clamp and allows the spindle axis to rotate together with the spindle clamp when the spindle axis is positioned inside the opening of the spindle clamp,
wherein
at least one spindle can be set in a free rotational movement when the spindle is positioned outside of the opening of the spindle clamp and the spindle is driven by a moving chain through the spindle gear.

20. A method for moving at least one spindle on a carrier that can move from one painting, coating or treatment module to another through a transport belt, the carrier comprising:
at least one spindle supporting a substrate holder;
the spindle comprising a spindle gear;
a coupling gear which is driven by a chain, wherein the coupling gear is coupled through a coupling rod to a spindle clamp, wherein the spindle clamp is positioned on the axis of the at least one spindle and having at least one opening allowing the axis of the spindle to be moved in and out of the spindle clamp
wherein
the axis of the spindle comprises at least one part which has a shape that is at least partially matching the shape of the open insert of the spindle clamp so that the axis of the spindle is mechanically coupled with the spindle clamp and allows the spindle axis to rotate together with the spindle clamp when the spindle axis is positioned inside the opening of the spindle clamp,
wherein
at least one spindle can rotate back and forth on its axis at the same time that the carrier is moving horizontally back and forth inside the module through the transport belt.
